(19) United States
(12) Patent Application Publication
(10) Pub. No.: US 2025/0368500 A1
(43) Pub. Date: Dec. 4, 2025

(54) MEMS Package Structure

(71) Applicant: AAC ACOUSTIC TECHNOLOGIES (SHENZHEN) CO., LTD., Shenzhen (CN)

(72) Inventor: Leilei Ma, Shenzhen (CN)

(21) Appl. No.: 18/984,849

(22) Filed: Dec. 17, 2024

Related U.S. Application Data
(63) Continuation of application No. PCT/CN2024/095971, filed on May 29, 2024.

(51) Int. Cl. B81B 7/00; B81B 3/00; H01L 23/538

(52) U.S. Cl. CPC B81B 7/0061; B81B 3/0021; B81B 7/008; H01L 23/538; B81B 2201/0257

(57) ABSTRACT

The present invention provides a MEMS package structure including a housing, a circuit board, a MEMS chip and an ASIC chip. The MEMS chip includes a diaphragm. The circuit board includes an upper and a lower surface. The circuit board includes a first acoustic hole extending from the lower surface, a second acoustic hole extending from the upper surface, and a communication channel. A projection of the first acoustic hole and a projection of the second acoustic hole along a vibration direction of the diaphragm are non-overlapped with each other. Some protruding structures are located in communication channel. The protruding structures cause a pressure of an airflow entering from the first acoustic hole to be 2-3.5 times the pressure of the airflow exiting from the second acoustic hole. The MEMS package structure of present invention has a stronger ability of anti-air-blowing.

### FIELD OF THE PRESENT INVENTION

The present invention relates to the field of acoustic-electro conversion, and more particularly, to a MEMS package structure.

### DESCRIPTION OF RELATED ART

MEMS (Micro-electro Mechanical Systems) package structure is a package structure manufactured based on MEMS sensor technology, with improved noise cancellation performance, good RF performance and ability to suppress electromagnetic interference. The MEMS package structure is widely used in smart phones, in-line headphones, tablets and laptops and other types of electronic products.

In related art, the MEMS package structure includes the housing, the circuit board capped to the housing to form a receiving space, and the ASIC chip and the MEMS chip disposed in the receiving space. The MEMS chip is located on the circuit board. The diaphragm of the MEMS chip divides the receiving space into a front cavity and a back cavity. The circuit board is provided with a through-hole connected to the front cavity. When an atmospheric pressure enters through the through-hole, the airflow directly acts on the diaphragm of the MEMS chip, which is prone to lead to rupture of the diaphragm, and the resistance of the MEMS package structure to blowing is weak.

Therefore, it is desired to provide a new MEMS package structure which can overcome the above problems.

### SUMMARY

In view of the above, the embodiments of the present invention provide a new MEMS package structure having a stronger ability of anti-air-blowing.

The present invention provides a MEMS package structure including a housing, a circuit board cooperating to form a receiving room with the housing, a MEMS chip and an ASIC chip located in the receiving room. The MEMS chip includes a diaphragm and a back plate spaced apart from the diaphragm. The circuit board includes an upper surface connected with the MEMS chip and a lower surface opposite to the upper surface. The circuit board further includes a first acoustic hole extending from the lower surface to the upper surface and not passing through the upper surface, a second acoustic hole extending from the upper surface to the lower surface and not passing through the lower surface, and a communication channel disposed between the upper surface and the lower surface communicating the first acoustic hole and the second acoustic hole. The MEMS chip covers the second acoustic hole. A projection of the first acoustic hole and a projection of the second acoustic hole along a vibration direction of the diaphragm are non-overlapped with each other. A plurality of protruding structures are provided in the communication channel. The protruding structures cause a pressure of an airflow entering from the first acoustic hole to be 2-3.5 times the pressure of the airflow exiting from the second acoustic hole.

As an improvement, the protruding structures extend from the lower surface and does not reach the upper surface, or the protruding structures extend from the upper surface and does not reach the lower surface.

As an improvement, the circuit board is a laminated circuit board, and the circuit board includes a first circuit board connected to the MEMS chip, a second circuit board spaced apart from the first circuit board, and a third circuit board disposed between the first circuit board and the second circuit board, the third circuit board being a hollow annular structure, the second acoustic hole penetrating the first circuit board, and the first acoustic hole penetrating the second circuit board.

As an improvement, the plurality of the protruding structures are arranged in a Tesla valve structure.

As an improvement, the plurality of the protruding structures cause the airflow entering from the first acoustic hole to reach the second acoustic hole along at least two different paths.

As an improvement, the airflow entering the circuit board from the first acoustic hole contacts the protruding structures to create turbulence to reduce the pressure of the airflow.

As an improvement, the protruding structures are flat plate structures, and an angle between adjacent protruding structures is 10°-170°.

As an improvement, the protruding structures are flat plate structures, and/or curved plate structures, and/or curved block structures.

As an improvement, a number of the protruding structures is 1-1000.

As an improvement, wherein the diaphragm is closer to the circuit board than the back plate.

### BRIEF DESCRIPTION OF THE DRAWINGS

Many aspects of the exemplary embodiments can be better understood with reference to the following drawing. The components in the drawing are not necessarily drawn to scale, the emphasis instead being placed upon clearly illustrating the principles of the present invention. Moreover, in the drawings, like reference numerals designate corresponding parts throughout the several views.

FIG. 1 is an illustrative cross-sectional view of the MEMS package structure according to the first embodiment of the present invention.

FIG. 2 is an illustrative cross-sectional view of the circuit board of the MEMS package structure according to the first embodiment of the present invention.

FIG. 3 is an illustrative cross-sectional view of the circuit board of the MEMS package structure according to the second embodiment of the present invention.

FIG. 4 is an illustrative cross-sectional view of the circuit board of the MEMS package structure according to the third embodiment of the present invention.

FIG. 5 is an illustrative cross-sectional view of the circuit board of the MEMS package structure according to the fourth embodiment of the present invention.

FIG. 6 is an illustrative cross-sectional view of the circuit board of the MEMS package structure according to the fifth embodiment of the present invention.

### DETAILED DESCRIPTION OF THE EXEMPLARY EMBODIMENTS

The present invention will hereinafter be described in detail with reference to exemplary embodiments. To make the technical problems to be solved, technical solutions and beneficial effects of the present invention more apparent, the present invention is described in further detail together with the figures and the embodiments. It should be understood the specific embodiments described hereby is only to explain the disclosure, not intended to limit the disclosure.

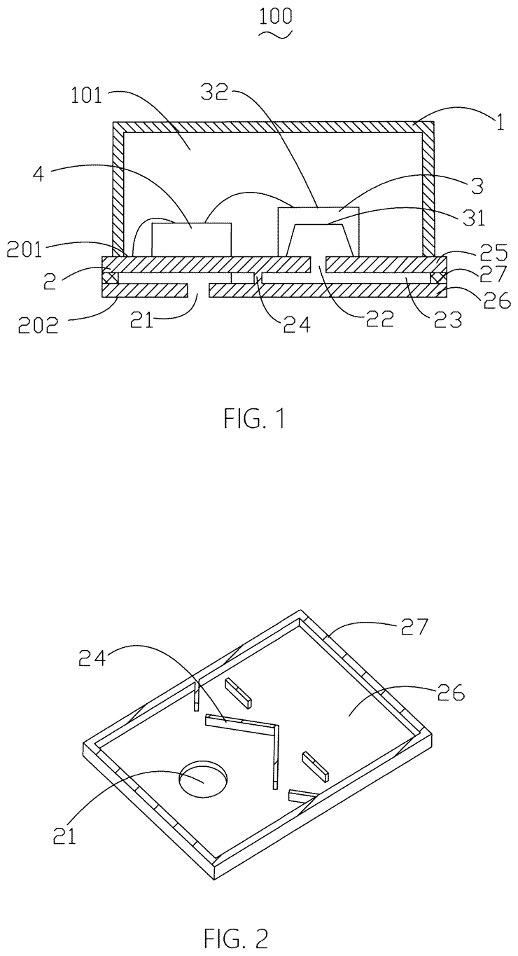

Referring to the FIGS. 1 and 2, FIG. 1 is an illustrative cross-sectional view of the MEMS package structure according to the first embodiment of the present invention. The first embodiment of the present invention provides a MEMS package structure 100. The MEMS package structure 100 includes a housing 1, a circuit board 2 cooperating to form a receiving room 101 with the housing 1, a MEMS chip 3 and an ASIC chip 4 located in the receiving room 101. The MEMS chip 3 is connected with the circuit board 2. The housing 1 is made of metal material. The MEMS chip 3 includes a diaphragm 31 and a back plate 32 spaced apart from the diaphragm 31. The diaphragm 31 and back plate 32 form a capacitive structure. In this embodiment, the diaphragm 31 is provided closer to the circuit board 2 than the back plate 32, and in other embodiments, the back plate 32 may also be provided closer to the circuit board 2 than the diaphragm 31.

FIG. 2 is an illustrative cross-sectional view of the circuit board 2 along a thickness direction of the circuit board 2. Referring to the FIGS. 1 and 2, the circuit board 2 includes an upper surface 201 connected with the MEMS chip 3 and a lower surface 202 opposite to the upper surface 201. The circuit board 2 further includes a first acoustic hole 21 extending from the lower surface 202 to the upper surface 201 and not passing through the upper surface 201, a second acoustic hole 22 extending from the upper surface 201 to the lower surface 202 and not passing through the lower surface 202, and a communication channel 23 disposed between the upper surface 201 and the lower surface 202 communicating the first acoustic hole 21 and the second acoustic hole 22. The MEMS chip 3 covers the second acoustic hole 22. A projection of the first acoustic hole 21 and a projection of the second acoustic hole 22 along a vibration direction of the diaphragm 31 are non-overlapped with each other, so as to prevent dust outside from falling into the MEMS chip 3, and also to play a buffering role for the impact of an airflow from the outside world, so as to improve the reliability of the product.

A plurality of protruding structures 24 are provided in the communication channel 23. The protruding structures 24 cause a pressure of an airflow entering from the first acoustic hole 21 to be 2-3.5 times the pressure of the airflow exiting from the second acoustic hole 22.

The protruding structures 24 extend from the lower surface 202 and does not reach the upper surface 201, or the protruding structures 24 extend from the upper surface 201 and does not reach the lower surface 202. The protruding structures 24 are formed on the circuit board 2 by means of a finishing milling or deposition etching process. A ratio of height to width of the protruding structures 24 is 0.1-8.

The circuit board 2 is a laminated circuit board, and the circuit board 2 includes a first circuit board 25 connected to the MEMS chip 3, a second circuit board 26 spaced apart from the first circuit board 25, and a third circuit board 27 disposed between the first circuit board 25 and the second circuit board 26. The third circuit board 27 is a hollow annular structure. The second acoustic hole 22 penetrates the first circuit board 25, and the first acoustic hole 21 penetrates the second circuit board 26. The upper surface 201 is arranged on the first circuit board 25, and the lower surface 202 is arranged on the second circuit board 26. Optionally, the first acoustic hole 21 and the second acoustic hole 22 are located at a midline line along a long axis direction of the circuit board 2.

The plurality of the protruding structures 24 cause the airflow entering from the first acoustic hole 21 to reach the second acoustic hole 22 along at least two different paths. The airflow enters the circuit board 2 from the first acoustic hole 21 and then contacting the protruding structures 24 to generate turbulence to reduce the pressure of the airflow, thereby reducing the pressure of the airflow reaching the second acoustic hole 22, and furthermore, effectively reducing the pressure of the airflow reaching the diaphragm 31. Finally, the pressure of the airflow reaching the diaphragm 31 is made to be reduced by ½-⅔ compared to the pressure of the airflow reaching directly to the diaphragm in the prior art, thus the present invention ensures the stronger ability of anti-air-blowing of the diaphragm 31.

As shown in FIG. 2, it is the first embodiment of present invention. The protruding structures 24 are flat plate structures, and an angle between adjacent protruding structures 24 is 10°-170°. A number of the protruding structures 24 is 1-1000. The protruding structure 24 is symmetrically arranged around a centerline of the circuit board 2.

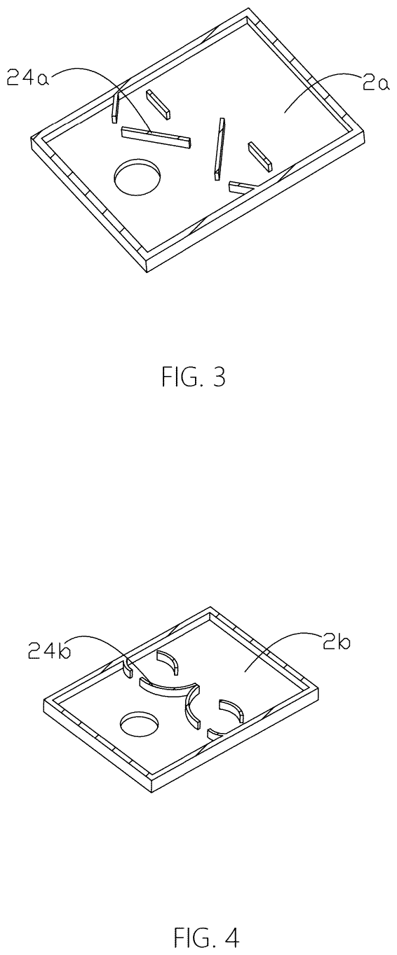

As shown in FIG. 3, it is a second embodiment of present invention. The protruding structures 24a are also flat plate structures, and the angle between adjacent protruding structures 24a is also 10°-170°. The protruding structure 24a is divided into two groups, and the two groups of protruding structure 24a are arranged staggered along a length direction of the circuit board 2a.

As shown in FIG. 4, it is a third embodiment of present invention. The protruding structures 24b are curved plate structures. The number of the protruding structures 24b is 1-1000. The protruding structures 24b are symmetrically arranged around the centerline of the circuit board 2b.

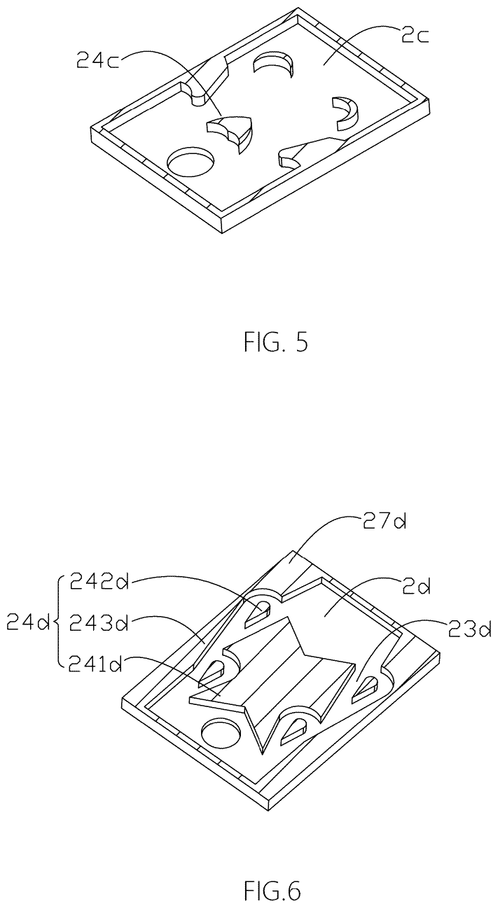

As shown in FIG. 5, it is a fourth embodiment of present invention. The protruding structures 4c are a combination of curved plate structures and curved block structures. The number of the protruding structures 24c is 1-1000. The protruding structures 24c are symmetrically arranged around the centerline of the circuit board 2c. In other embodiments, the protruding structures may also be a combination of flat plate structures, curved plate structures, and curved block structures.

As shown in FIG. 6, it is a fifth embodiment of present invention. The plurality of the protruding structures 24d are arranged in a Tesla valve structure. The protruding structures 24b are curved block structures. In details, the protruding structures 24d include a first protruding portion 241d, a plurality of second protruding portions 242d surrounding the first protruding portion 241d, and a third protruding portion 243d surrounding the second protruding portions 242d. The first protruding portion 241d is located at a middle position of the circuit board 2d. The second protruding portions 242d is in the shape of a water droplet. And the third protruding portion 243d extends from the third circuit board 27d into the communication channel 23d. The protruding structures 24d are symmetrically arranged around the centerline of the circuit board 2d.

Comparing with the related art, the present invention provides a MEMS package structure including a housing, a circuit board cooperating forming a receiving room with the housing, a MEMS chip and an ASIC chip located in the receiving room. The MEMS chip includes a diaphragm and a back plate spaced apart from the diaphragm. The circuit board includes an upper surface connected with the MEMS chip and a lower surface opposite to the upper surface. The circuit board further includes a first acoustic hole extending from the lower surface to the upper surface and not passing through the upper surface, a second acoustic hole extending from the upper surface to the lower surface and not passing through the upper surface, and a communication channel disposed between the upper surface and the lower surface communicating the first acoustic hole and the second acoustic hole. The MEMS chip covers the second acoustic hole. A projection of the first acoustic hole and a projection of the second acoustic hole along a vibration direction of the diaphragm are non-overlapped with each other. A plurality of protruding structures are provided in the communication channel. The protruding structures cause a pressure of an airflow entering from the first acoustic hole to be 2-3.5 times the pressure of the airflow exiting from the second acoustic hole.

The MEMS package structure of the present invention, by setting several protruding structures inside the circuit board, can effectively reduce the pressure of the airflow after the airflow reaching the second acoustic hole, thereby reducing the pressure of the airflow reaching the diaphragm by ½-⅔ compared to the pressure of the airflow directly reaching the diaphragm in the prior art, thus buffering the impact force of air pressure on the diaphragm of the MEMS chip.

It is to be understood, however, that even though numerous characteristics and advantages of the present exemplary embodiments have been set forth in the foregoing description, together with details of the structures and functions of the embodiment, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A MEMS package structure, comprising:
a housing;
a circuit board cooperating to form a receiving room with the housing, the circuit board comprising an upper surface and a lower surface opposite to the upper surface;
a MEMS chip located in the receiving room, the MEMS chip comprising a diaphragm and a back plate spaced apart from the diaphragm; and
an ASIC chip located in the receiving room;
wherein the MEMS chip is connected on the upper surface of the circuit board, the circuit board further comprises a first acoustic hole extending from the lower surface to the upper surface and not passing through the upper surface, a second acoustic hole extending from the upper surface to the lower surface and not passing through the lower surface, and a communication channel disposed between the upper surface and the lower surface communicating the first acoustic hole and the second acoustic hole, the MEMS chip covers the second acoustic hole, a projection of the first acoustic hole and a projection of the second acoustic hole along a vibration direction of the diaphragm are non-overlapped with each other, a plurality of protruding structures are provided in the communication channel, the protruding structures cause a pressure of an airflow entering from the first acoustic hole to be 2-3.5 times the pressure of the airflow exiting from the second acoustic hole.

2. The MEMS package structure as described in claim 1, wherein the protruding structures extend from the lower surface and does not reach the upper surface, or the protruding structures extend from the upper surface and does not reach the lower surface.

3. The MEMS package structure as described in claim 1, wherein the circuit board is a laminated circuit board, and the circuit board comprises a first circuit board connected to the MEMS chip, a second circuit board spaced apart from the first circuit board, and a third circuit board disposed between the first circuit board and the second circuit board, the third circuit board being a hollow annular structure, the second acoustic hole penetrating the first circuit board, and the first acoustic hole penetrating the second circuit board.

4. The MEMS package structure as described in claim 1, wherein the plurality of the protruding structures are arranged in a Tesla valve structure.

5. The MEMS package structure as described in claim 1, wherein the plurality of the protruding structures cause the airflow entering from the first acoustic hole to reach the second acoustic hole along at least two different paths.

6. The MEMS package structure as described in claim 1, wherein the airflow entering the circuit board from the first acoustic hole contacts the protruding structures to create turbulence to reduce the pressure of the airflow.

7. The MEMS package structure as described in claim 6, wherein the protruding structures are flat plate structures, and an angle between adjacent protruding structures is 10°-170°.

8. The MEMS package structure as described in claim 6, wherein the protruding structures are flat plate structures, and/or curved plate structures, and/or curved block structures.

9. The MEMS package structure as described in claim 6, wherein a number of the protruding structures is 1-1000.

10. The MEMS package structure as described in claim 1, wherein the diaphragm is closer to the circuit board than the back plate.
